(19) United States
(12) Patent Application Publication
(10) Pub. No.: US 2025/0280577 A1
(43) Pub. Date: Sep. 4, 2025

(54) ELECTRONIC DEVICE INCLUDING A POWER TRANSISTOR

(71) Applicant: Semiconductor Components Industries, LLC, Scottsdale, AZ (US)

(72) Inventors: Gary Horst LOECHELT, Tempe, AZ (US); Peter MOENS, Erwetegem (BE)

(73) Assignee: Semiconductor Components Industries, LLC, Scottsdale, AZ (US)

(21) Appl. No.: 18/593,211

(22) Filed: Mar. 1, 2024

(51) Int. Cl. H01L 29/06; H01L 21/04; H01L 29/16; H01L 29/66; H01L 29/78

(52) U.S. Cl. CPC H10D 62/114; H10D 12/031; H10D 30/668; H10D 62/8325; H01L 21/0465

(57) ABSTRACT

An electronic device can include a substrate and a carrier accumulation region. In an implementation, the electronic device can further include a gap region, and a buried shield. The gap region is along a majority carrier flow path between substrate and the carrier accumulation region. In another implementation, the electronic device can further include a carrier distribution layer, a body region, and a body contact region. The body contact region has a second conductivity type and electrically couples the buried shield to the body region. The gap region can be along a majority carrier flow path between the carrier accumulation region and the carrier distribution layer. In a further implementation, the electronic device can include a gate member and an intermediate region between source regions. The gate member can include gate electrodes within gate trenches and an intermediate portion overlapping the intermediate region.

### FIELD OF THE DISCLOSURE

The present disclosure relates to electronic devices, and more particularly, to electronic devices that include power transistors.

### RELATED ART

Transistors can be designed to operate at relatively high voltages and high currents. Some semiconductor materials, such as monocrystalline Si, may not be able to operate at such high voltages and currents or may need complex designs to withstand the high voltages and current during operation. SiC can be used in transistors that operate at high voltages and current. Specific on-state resistance (R_{SP}) may be higher than desired, and scaling transistors to smaller dimensions can be challenging. Further improvement in reducing R_{SP} and reducing dimensions are desired.

### BRIEF DESCRIPTION OF THE DRAWINGS

Implementations are illustrated by way of example and are not limited in the accompanying figures.

FIG. 1 includes an illustration of a cross-sectional view of a portion of a workpiece that includes a substrate and a semiconductor layer.

FIG. 2 includes an illustration of a cross-sectional view of the workpiece of FIG. 1 after forming a carrier distribution layer, a carrier accumulation region, and a body region.

FIG. 3 includes an illustration of a top view of the workpiece of FIG. 2 after forming a buried shield mask.

FIG. 4 includes an illustration of a cross-sectional view of the workpiece of FIG. 3 after forming buried shields.

FIG. 5 includes an illustration of a top view of the workpiece of FIG. 4 after forming sidewall spacers and forming source regions.

FIG. 6 includes an illustration of a cross-sectional view of the workpiece of FIG. 5.

FIG. 7 includes an illustration of a top view of the workpiece of FIG. 6 after forming a body contact mask.

FIG. 8 includes an illustration of a cross-sectional view of the workpiece of FIG. 7 after forming body contact regions.

FIG. 9 includes an illustration of a top view of the workpiece of FIG. 8 after forming a gate trench mask.

FIG. 10 includes an illustration of a top view of the workpiece of FIG. 9 after defining gate trenches and removing the gate trench mask.

FIG. 11 includes an illustration of a perspective view of a portion of the workpiece of FIG. 10.

FIG. 12 includes an illustration of a top view of the workpiece of FIGS. 10 and 11 after forming a gate dielectric layer, a gate conductive layer, and a gate mask.

FIG. 13 includes an illustration of a top view of the workpiece of FIG. 12 after forming gate members and removing the gate mask.

FIG. 14 includes an illustration of a perspective view of a portion of the workpiece of FIG. 13.

FIG. 15 includes an illustration of a cross-sectional view of a portion of the workpiece of FIG. 13 illustrating majority carrier flow from the carrier accumulation region to the semiconductor layer.

FIG. 16 includes an illustration of a top view of the workpiece of FIGS. 13 and 14 after forming a contact mask.

FIG. 17 includes an illustration of a top view of the workpiece of FIG. 13 with openings in the contact mask superimposed over features in the workpiece.

FIG. 18 includes an illustration of a perspective view of a portion of the workpiece of FIG. 16 after forming a source electrode.

FIG. 19 includes an illustration of a top view of the workpiece of FIG. 2 after forming source regions and body contact regions.

FIG. 20 includes an illustration of a top view of the workpiece of FIG. 19 after defining gate trenches.

FIG. 21 includes an illustration of a perspective view of a portion of the workpiece of FIG. 20 after forming a gate dielectric layer and gate members.

FIG. 22 includes an illustration of a top view of the workpiece of FIG. 21 after forming an interlayer dielectric layer and defining contact openings extending through the interlayer dielectric layer.

FIG. 23 includes an illustration of a perspective view of a portion of the workpiece of FIG. 22 after forming a source electrode.

FIG. 24 includes plots of R_{SP} as a function of vertical distance for different designs of power transistors when electronic devices are at 25° C.

FIG. 25 includes plots of R_{SP} as a function of vertical distance for the different designs of power transistors when electronic devices are at 175° C.

FIG. 26 includes plots of maximum E_{OX} as a function of V_{DS} for the different designs of power transistors.

Skilled artisans appreciate that elements in the figures are illustrated for simplicity and clarity and have not necessarily been drawn to scale. For example, the dimensions of some of the elements in the figures may be exaggerated relative to other elements to help to improve understanding of implementations of the inventive concepts.

### DETAILED DESCRIPTION

The following description in combination with the figures is provided to assist in understanding the teachings disclosed herein. The following description will focus on specific implementations and implementations of the teachings. This focus is provided to assist in describing the teachings and should not be interpreted as a limitation on the scope or applicability of the teachings. However, other implementations can be used based on the teachings as disclosed in this application.

As used in this specification, length and width are measured in directions along or parallel to a major surface of a substrate or a semiconductor layer. Depth, height, and thickness are measured in directions perpendicular to the major surface of the substrate or the semiconductor layer.

The term “electrically coupled” is intended to mean a connection, linking, or association of two or more electronic components, circuits, systems, or any combination of: (1) at least one electronic component, (2) at least one circuit, or (3) at least one system in such a way that a signal (e.g., current, voltage, or optical signal) may be partly or completely transferred from one to another. A subset of “electrically coupled” can include an electrical connection between two electronic components. In a circuit diagram, a node corresponds to an electrical connection between the electronic components. Thus, an electrical connection is a specific type of electrical coupling; however, not all electrical couplings are electrical connections. Other types of electrical coupling include capacitive coupling, resistive coupling, and inductive coupling.

The terms “horizontal,” “lateral,” and their variants are in directions along or parallel to a major surface of a substrate or semiconductor layer, and the terms “vertical,” “height,” “depth,” and their variants are in directions perpendicular to a major surface of the substrate or the semiconductor layer. Two objects that are laterally offset can be at the same or different elevations.

The terms “overlap,” “underlap,” and their variants refer to at least portions of regions or other features that lie along a vertical line that is perpendicular to a plane defined by a major surface. Components or features that overlap or underlap each other may or may not be in physical contact with each other.

The term “normal operation” and “normal operating conditions” refer to conditions under which an electronic component or device is designed to operate. The conditions may be obtained from a data sheet or other information regarding voltages, currents, capacitance, resistance, or other electrical conditions. Thus, normal operation does not include operating an electrical component or device well beyond its design limits.

The terms “power transistor” is intended to mean a transistor that has a drain-to-source breakdown voltage (BV_{DS}) of at least 400 V.

Unless explicitly stated to the contrary, a border between a relatively heavier doped region or layer and an immediately adjacent and relatively lighter doped region or layer of the same conductivity type is where the dopant concentration between the regions or layers is 1.1 times higher than a peak dopant concentration of the relatively lower doped region or layer.

The terms “on,” “overlying,” and “over” may be used to indicate that two or more elements are in direct physical contact with each other. However, “over” may also mean that two or more elements are not in direct contact with each other. For example, “over” may mean that one element is above another element, but the elements do not contact each other and may have another element or elements between the two elements.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements, components and other features described herein. This is done merely for convenience and to give a general sense of the scope of the inventive concepts. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

The use of the word “about,” “approximately,” or “substantially” is intended to mean that a value of a parameter is close to a stated value or position. However, minor differences may prevent the values or positions from being exactly as stated. Thus, differences of up to ten percent (10%) (and up to twenty percent (20%) for semiconductor doping concentrations) for the value are reasonable differences from the ideal goal of exactly as described.

Unless otherwise defined, all technical and scientific terms used herein have the same meaning as commonly understood by one of ordinary skill in the art to which these inventive concepts belongs. The materials, methods, and examples are illustrative only and not intended to be limiting. To the extent not described herein, many details regarding specific materials and processing acts are conventional and may be found in textbooks and other sources within the semiconductor and electronic arts.

The concepts described herein can be used for an electronic device that includes a transistor having a BV_{DS} of at least 400 V. The design is well suited for a transistor having BV_{DS} of at least 500 V or at least 600 V. In another implementation, the design works well for a transistor having a higher BV_{DS}, such as 700 V or 850 V. In any of the preceding or a different implementation, the transistor may have a BV_{DS} of at most 2500 V. In a further implementation, the transistor may have a BV_{DS} outside the previously described values.

Transistor structures making up the transistor can have active regions that include SiC. The transistor can include carrier accumulation regions that can help to reduce R_{SP}. The transistor can further include buried shield regions. The buried shield can help to shield the gate dielectric layer, so that the electrical field across the gate dielectric layer can be reduced and allow dimensions of the transistor to be reduced. The transistor can also include a carrier distribution layer to help redistribute majority carriers before they enter a semiconductor layer, where the semiconductor layer can be a drift region for the transistor. In an implementation, a cell within the transistor can include more than one gate trench segment that can help to increase the current that flows through the cell when the transistor is in an on-state. In another implementation, a continuous gate trench can have a length extending along all of the cell and simplify the design of the transistor.

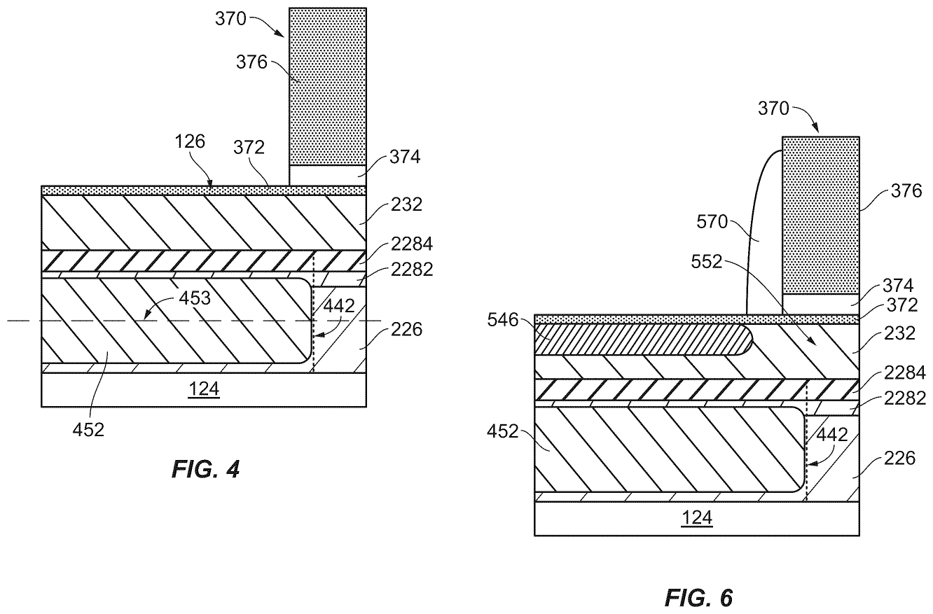

In an aspect, an electronic device can comprise a transistor. The transistor can comprise a substrate having a first conductivity type; a carrier accumulation region having the first conductivity type; a buried shield having a second conductivity type opposite the first conductivity type and being between the carrier accumulation region and the substrate; and a gap region having the first conductivity type, wherein the gap region is defined at least in part by the buried shield. The gap region is along a majority carrier flow path between the substrate and a portion of the carrier accumulation region overlapping the buried shield, and the carrier accumulation region has a peak dopant concentration that is greater than a dopant concentration of the gap region along the mid-elevation line of the buried shields, where the buried shields and mid-elevation line are described in more detail with respect to FIG. 4.

In another aspect, an electronic device can include a substrate having a first conductivity type, a carrier distribution layer having the first conductivity type, a gap region having the first conductivity type, a carrier accumulation region having the first conductivity type, and a body region having a second conductivity type. The body region can include a channel region of a vertical transistor above the carrier accumulation region. A portion of the carrier distribution layer can be within the gap region, and the gap region can be along a majority carrier flow path between the carrier accumulation region and the carrier distribution layer. A peak dopant concentration of the carrier distribution layer is greater than a background dopant concentration.

In a further aspect, an electronic device can include a substrate having a first conductivity type and a carrier accumulation region having the first conductivity type and being electrically coupled to the substrate. The electronic device can further include a first source region having the first conductivity type, a second source region having the first conductivity type, and an intermediate region having a second conductivity type opposite the first conductivity type. The first source region can be part of a first vertical transistor structure, and the second source region can be a part of a second vertical transistor structure. The intermediate region can be laterally between the first source region and the second source region and at an elevation higher than the carrier accumulation region. The electronic device can still further include a first gate trench extending through the first source region, and a second gate trench extending through the second source region. The electronic device can include a gate member having a portion lying within the first gate trench, another portion lying within the second gate trench, and a further portion overlapping the intermediate region. The gate member can include a first gate electrode for the first vertical transistor structure and a second gate electrode for the second vertical transistor structure.

In the description below, doped layers and doped regions are described with respect to dopant concentrations and depths and vertical positions (in a direction perpendicular to a major surface) and lengths and widths (along a plane or parallel to the major surface) in a finished device, such as after source metal is formed, rather than at the time of doping. Skilled artisans will be able to perform simulations to determine doses and energies to be used at the time of doping to achieve the doped layers and doped regions in the finished device.

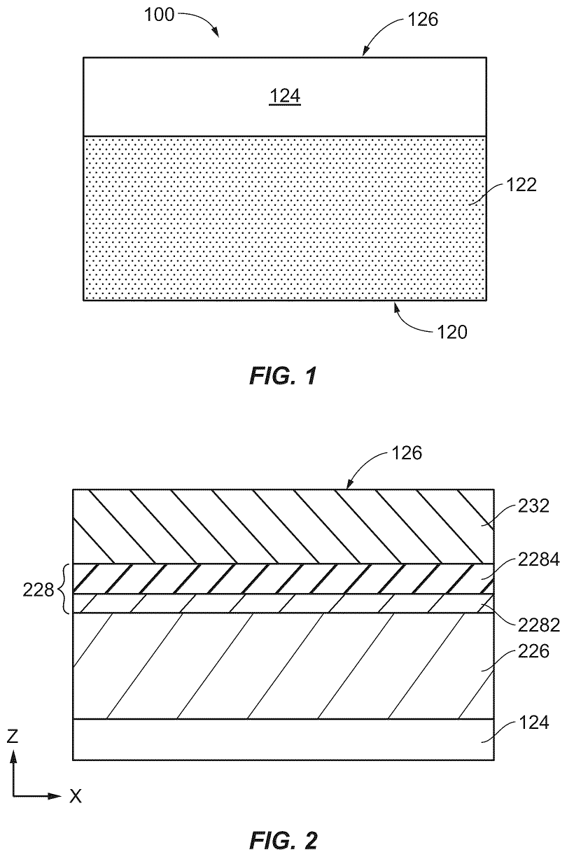

FIG. 1 includes a cross-sectional view of a portion of a workpiece 100 that includes a substrate 122 and a semiconductor layer 124. The substrate 122 can be a monocrystalline semiconductor wafer, a semiconductor-on-insulator (SOI) wafer, or the like. In an implementation, the substrate 122 can be in a form of a wafer. The substrate 122 and the semiconductor layer 124 can include a wide bandgap semiconductor material, and in a particular implementation, SiC is the semiconductor material within the semiconductor layer 124 and is the semiconductor material within at least the portion of the substrate 122 that contacts the semiconductor layer 124. In an implementation, the SiC can be a 3C, a 4H, or a 6H polytype.

The semiconductor material within the substrate 122 can have a dopant concentration of at least 1×10¹⁸ atoms/cm³. In a particular implementation, the dopant concentration can be at least 1×10¹⁹ atoms/cm³ to ensure an ohmic contact to a drain electrode that is subsequently attached to or formed along a back side major surface 120. The semiconductor material within the substrate 122 can be n-type doped or p-type doped. The majority carriers for the power transistor can be electrons, and the semiconductor material can be n-type doped. In this specification, n-type dopants can be N or P, and a p-type dopant can be Al.

The semiconductor layer 124 can be epitaxially grown and doped during or after growth. The semiconductor layer 124 can have a thickness in a range from 4.0 microns to 20.0 microns. The semiconductor layer 124 can have the same conductivity type as the semiconductor material within the substrate 122. In an implementation, the semiconductor layer 124 is n-type doped. The semiconductor layer 124 can have a lower dopant concentration as compared to the semiconductor material within the substrate 122. The average dopant concentration of the semiconductor layer 124 can be in a range from 2×10¹⁵ atoms/cm³ to 3×10¹⁶ atoms/cm³. The average dopant concentration of the semiconductor layer 124 before any further doping, such as for a body region or a source region, is referred to herein as the background dopant concentration. The uppermost surface of the semiconductor layer 124 is the front side major surface 126. Subsequent doping and patterning will be performed along the front side major surface 126.

One or more epitaxial layers may be grown between substrate 122 and semiconductor layer 124. These additional layers may serve a number of functions including, such as, providing a transition buffer at the start of epitaxial growth, a layer for isolating crystal defects from the semiconductor layer 124, or a layer for improving stability at high current operation (i.e., safe operating area improvement). In these aforementioned cases, the additional layers usually have a higher doping concentration than semiconductor layer 124, have low resistivity because of their high doping concentration, and provide little additional benefit in blocking voltage.

A mask (not illustrated) can be formed over the major surface 126 of the semiconductor layer 124. The active area for transistor structures of the power transistor being formed is exposed. The mask covers areas where electronic components and circuits are outside the active area for the transistor structures.

Referring to FIG. 2, doping can be performed to form a carrier distribution layer 226, a carrier accumulation region 228, and a body region 232. The order of formation of the carrier distribution layer 226, the carrier accumulation region 228, and body region 232 can be performed in any order relative to one another.

In this specification, doping for each layer or region can be performed as a single ion implantation or as a plurality of ion implantations where each ion implant is performed at a different energy as compared to one or more other ion implantations within the plurality of ion implantations. After reading this specification, for each doping, skilled artisans will be able to determine the number of ion implantations, dose(s), and energy(ies) for a particular doping species (e.g., N (n-type), P (n-type), or Al (p-type)) to achieve desired doping depth(s) and a dopant concentration profile.

The carrier distribution layer 226 can help to redistribute majority carriers along a flow path from subsequently-formed carrier accumulation regions to the semiconductor layer 124 via subsequently defined gap regions. The carrier distribution layer 226 is located below the carrier accumulation region 228. The carrier distribution layer 226 has the same conductivity type as the semiconductor layer 124. In an implementation, the carrier distribution layer 226 is n-type doped. The carrier distribution layer 226 can have a peak dopant concentration that is greater than the average dopant concentration of the semiconductor layer 124 and less than an order of magnitude higher than the average dopant concentration of the semiconductor layer 124. The carrier distribution layer 226 can have a peak dopant concentration that is in a range from 4×10¹⁶ atoms/cm³ to 8×10¹⁷ cm³. The peak dopant concentration for the carrier distribution layer 226 can be at an elevation that is 0.7 microns to 2.0 microns below the major surface 126. In a particular implementation, the dopant concentration for the carrier distribution layer 226 may have a dopant concentration gradient where a dopant concentration of the carrier distribution layer 226 at a location closer to the carrier accumulation region 228 is greater than a dopant concentration of the carrier distribution layer 226 at a different location closer to substrate 122. The carrier distribution layer 226 can fully deplete during reverse bias under normal operating conditions.

Gap regions will be defined by portions of carrier distribution layer 226, the carrier accumulation region 228, and subsequently-formed buried shields and allow majority carriers to flow along a path around the subsequently-formed buried shields to the semiconductor layer 124. The carrier accumulation region 228 is located above the carrier distribution layer 226. The carrier accumulation region 228 has the same conductivity type as the semiconductor layer 124. In an implementation, the carrier accumulation region 228 is n-type doped. In the implementation as illustrated in FIG. 2, the carrier accumulation region 228 includes a deep portion 2282 and a shallow portion 2284. The terms “deep” and “shallow” are used with respect to distance from the major surface 126 and not with respect to thickness (as measured in the Z-direction). As compared to each other, the shallow portion 2284 may have a thickness that is thicker, the same as, or thinner than the deep portion 2282.

In a finished device, the carrier accumulation region 228 can be at an elevation that extends from 0.3 microns below the major surface 126 up to 1.5 microns below the major surface 126. The carrier accumulation region 228 can have a thickness (measured in the Z-direction) in a range from 0.2 micron to 0.5 micron. A thickness of the shallow portion 2284 can be in a range from 20% to 90% of a thickness of a combined thickness of the portions 2282 and 2284.

The deep portion 2282 can have a substantially uniform dopant concentration as a function of elevation from the major surface or may have a dopant concentration gradient where a dopant concentration of the deep portion 2282 at a location closer to the body region 232 is greater than a dopant concentration of the deep portion 2282 at a different location closer to the carrier distribution layer 226. The average dopant concentration of the deep portion 2282 can be 1.2 to 8 times higher than the average dopant concentration of the carrier distribution layer 226. The deep portion 2282 can have a peak dopant concentration that is in a range from 1×10¹⁷ atoms/cm³ to 2×10¹⁸ cm³.

When the power transistor is on, the shallow portion 2284 helps to collect electrons from the source regions so that the electrons flow more readily to gap regions (addressed with respect to FIG. 4) as compared to the shallow portion 2284 not being present. The peak dopant concentration within the shallow portion 2284 is greater than the peak dopant concentration of each of the carrier distribution layer 226 and the deep portion 2282. In an implementation, the peak dopant concentration in the shallow portion 2284 is in a range from 2×10¹⁷ atoms/cm³ to 4×10¹⁸ atoms/cm³. In the same or different implementation, the peak dopant concentration of the shallow portion 2284 is in a range from 0.2 micron to 0.7 micron from the major surface 126. Like the deep portion 2282, the shallow portion 2284 can fully deplete during reverse bias under normal operating conditions. The dopant concentration for the shallow portion 2284 can be higher than the dopant concentration of the deep portion 2282 because of the two-sided depletion from body region and the buried shields described in more detail below.

In an alternative implementation, the shallow portion 2284 can be eliminated and the dopant concentration of the deep portion 2282 can be increased. This alternative implementation may eliminate one ion implantation operation but may also result in a higher on-state resistance, a lower breakdown voltage, or both, for the device, depending upon the amount with which the dopant concentration of the deep portion 2282 is increased with respect to an implementation that includes the shallow portion 2284.

If needed or desired, one or more thin layers may be formed in addition to the carrier distribution layer 226 and the carrier accumulation region 228 to provide a more gradual dopant concentration gradient between the semiconductor layer 124 and the body region 232. The carrier accumulation region 228 can fully deplete during reverse bias under normal operating conditions. Its dopant concentration can be higher than the dopant concentration of the carrier distribution layer 226 because its closer proximity to the body region 232 aids in the depletion of this layer under reverse bias conditions.

The body region 232 includes channel regions for transistor structures making up the power transistor. The body region 232 has a conductivity type that is opposite any one or more of the semiconductor layer 124, the carrier distribution layer 226, or the carrier accumulation region 228. In an implementation, the body region 232 can be p-type doped. A peak dopant concentration of the body region 232 is greater than the average dopant concentration of the semiconductor layer 124. In an implementation, the peak dopant concentration is in a range from 8×10¹⁷ atoms/cm³ to 8×10¹⁸ atoms/cm³. A peak dopant concentration for the body region 232 can be at an elevation that is in a range from 0.1 microns to 0.6 microns below the major surface 126. Unlike the carrier distribution layer 226 and the carrier accumulation region 228, the body region 232 may not fully deplete during reverse bias under normal operating conditions. These depletion conditions for the carrier distribution layer 226 and the carrier accumulation region 228 can be used to determine their maximum dopant concentrations for a given device geometry, and the depletion condition for the body region 232 can be used to determine a lower value for the dopant concentration for a given device geometry. The first mask can be removed after doping for the carrier distribution layer 226, and carrier accumulation region 228, and the body region 232 is completed.

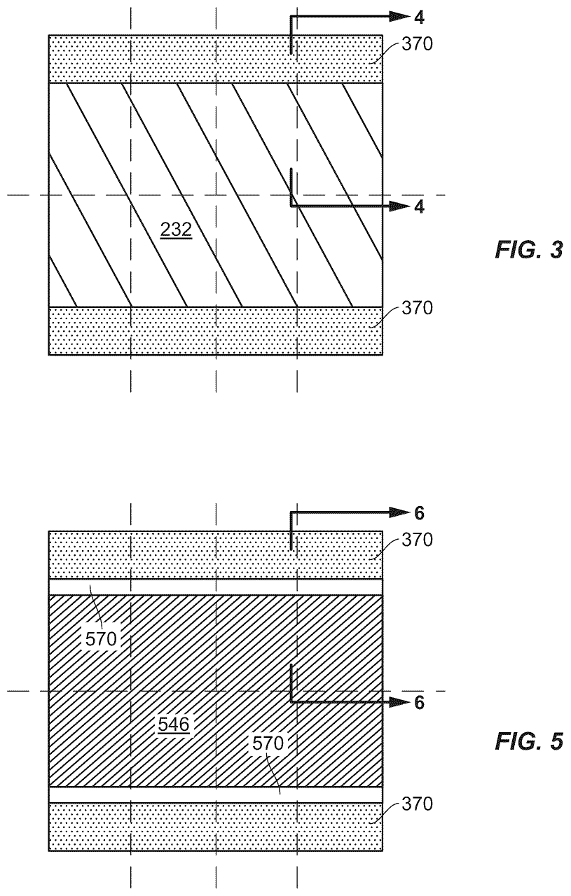

FIG. 3 includes a top view, and FIG. 4 includes a cross-sectional view along sectioning line 4-4 in FIG. 3 of a buried shield hard mask 370 formed over the body region 232. In FIG. 3 and other top views, the dashed lines correspond to borders of cells within the power transistor. The design as illustrated in FIG. 3 includes two rows and four columns of cells in a 2×4 configuration. Many other cells are present within the power transistor but are not illustrated in FIG. 3. Although an oxide layer 372 is illustrated in FIG. 4, FIG. 3 does not illustrate the portion of the oxide layer 372 that is exposed to improve understanding of positional relationships between the buried shield hard mask 370 and the body region 232 in FIG. 3.

The buried shield hard mask 370 is used in forming buried shields 452 as illustrated in FIG. 4. The buried shield hard mask 370 covers gap regions 442, where a border of one such regions is illustrated with a dashed line in FIG. 4, that are portions of the carrier distribution layer 226 and carrier accumulation region 228 that are between the buried shields 452.

The buried shield hard mask 370 can include a relatively thinner oxide layer 372, a polycrystalline silicon (polysilicon) layer 374, and a relatively thicker oxide layer 376. Of the three layers, the body region 232 is closest to the relatively thinner oxide layer 372 and farthest from the relatively thicker oxide layer 376. The relatively thinner oxide layer 372 can have a thickness in range from 10 nm to 90 nm. In the same or different implementation, the polysilicon layer 374 can have a thickness in a range from 30 nm to 300 nm. In the same or a further different implementation, the relatively thicker oxide layer 376 can have a thickness in a range from 0.9 micron to 4.0 microns. The polysilicon layer 374 and the relatively thicker oxide layer 376 can be patterned, and the relatively thinner oxide layer 372 can remain unpatterned during implantation. The relatively thinner oxide layer 372 can help to reduce the likelihood of implant channeling within the monocrystalline SiC when doping to form the subsequently-formed carrier accumulation regions and buried shields. Also, for SiC, higher dose implants can be performed at elevated temperatures to reduce implant damage. If the temperature for the ion implantation exceeds the temperature that conventional photoresist materials can withstand, a hard mask may be used instead.

The buried shields 452 help to shield subsequently-formed gate electrodes from the drain voltage of the power transistor and can be used to limit or reduce the saturation current of the device when operated in short-circuit. The ability to survive short-circuit events on the order of several microseconds is important for some applications such as motor drives and traction inverters. Limiting this current during a short-circuit event can extend the survival time for the device. A mid-elevation line 453 is where half of a thickness of the buried shield 452 is above the mid-elevation line, and another half of the thickness of buried shield 452 is below the mid-elevation line 453. As illustrated in FIG. 4, the mid-elevation line 453 is halfway between the interface of the buried shield 452 and the carrier accumulation region 228 and the interface of the buried shield 452 and the carrier distribution layer 226. The peak dopant concentration of the carrier accumulation region 228 is greater than the dopant concentration within the gap region 442 along the mid-elevation line 453.

Some of the dopant for the buried shields 452 extends beyond the edge of the buried shield hard mask 370 due to scattering because of the energy(ies) of the implant(s). The buried shields 452 have the same conductivity type as the body region 232. In an implementation, the buried shields 452 can be p-type doped. The buried shields 452 have a dopant concentration sufficient to counter dope portions of the carrier distribution layer 226 and the carrier accumulation region 228. The peak dopant concentration of the buried shields 452 can be the same or different from the peak dopant concentration of the body region 232. In the same or different implementation, a peak dopant concentration of the buried shields 452 can be in a range from 8×10¹⁷ atoms/cm³ to 2×10¹⁹ atoms/cm³. In the same or a further implementation, the peak dopant concentration for the buried shields 452 can be at an elevation in a range from 0.3 microns to 0.9 microns below the major surface 126. Each of the gap regions 442 can have a narrowest width that is in a range from 0.4 micron to 3.0 microns. Like the body region 232, the buried shields 452 may not fully deplete during reverse bias under normal operating conditions. However, unlike body regions 232 which can influence the threshold voltage of a subsequently formed transistor, fewer electrical characteristics of the device may depend upon the buried shields 452. Therefore, they can have a higher dopant concentration than the body regions 232, even beyond the 2×10¹⁹ atoms/cm³ limit suggested above. Concentrations above this limit may be possible but may not significantly improve the drain voltage shielding properties of the buried shields 452.

In an implementation, the shallow portion 2284 may be formed after the buried shield implant mask is formed. Thus, the shallow portion 2284 may not extend into the gap regions 442. Such a design may be useful to reduce capacitive coupling between the gap regions 442 and subsequently-formed gate members that overlap the gap regions 442.

FIG. 5 includes a top view, and FIG. 6 includes a cross-sectional view along sectioning line 6-6 in FIG. 5. The sidewall spacers 570 displace subsequently-formed source regions laterally farther from the gap regions 442. A layer of material can be conformally deposited and anisotropically etched to form the sidewall spacers 570. The widths of the sidewall spacers 570 at their bases can be a function of the thickness of the layer as deposited. The thickness can be in a range from 0.05 micron to 0.5 micron. In the same or different implementation, the widths of the sidewall spacers 570 at their bases can be in a range from 0.05 micron to 0.5 micron. The material for the sidewall spacers 570 can be different from the material along the upper surface of the second hard mask. When the material along the upper surface is oxide, the layer of material can include polysilicon or a nitride.

Source regions 546 are aligned to the sidewall spacers 570. The source regions 546 can have the same conductivity type as the carrier accumulation regions 228, the gap regions 442, and the carrier distribution layer 226. In an implementation, the source regions 546 can be n-type doped. The source regions 546 can have a peak dopant concentration of at least 5×10²⁰ atoms/cm³. In an implementation, the source regions 546 can have a peak dopant concentration of at least 1×10¹⁹ atoms/cm³ to ensure a better ohmic contact to a subsequently-formed source electrode. In the same or different implementation, the peak dopant concentration may be at most 5×10²⁰ atoms/cm³, so that subsequently-formed body contact regions can be formed and counter dope portions of the source regions 546. In the same or a further different implementation, the source regions 546 can extend from the major surface 126 to a depth in a range from 0.1 micron to 0.4 micron. The buried shield hard mask 370 and spacers 570 can be removed.

Intermediate regions 552 are portions of the body region 232 that are along the major surface 126 and located laterally between the source regions 546. Intermediate regions 552 have mid-elevation points that are elevations higher than mid-elevation points of the shallow portion 2284. A mid-elevation point of a layer, region, or other feature is a point at an elevation that is halfway between an uppermost point and lowermost point of such layer, region, or other feature. The intermediate regions 552 can help to reduce capacitive coupling between subsequently-formed gate members and the underlying gap regions 442.

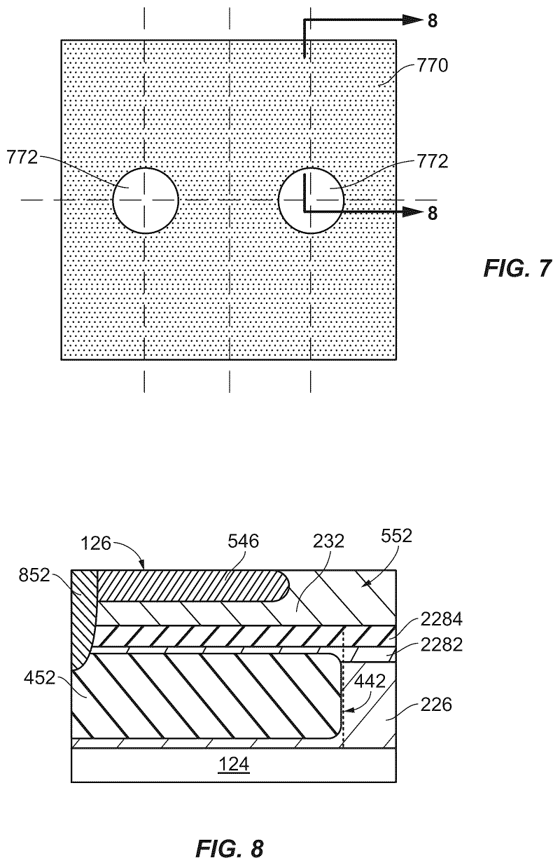

FIG. 7 includes a top view of a body contact mask 770. The body contact mask 770 can be formed and define body contact openings 772 that expose portions of the source regions 546 (not labelled in FIG. 7). The body contact mask 770 can have the same or a different composition as previously described with respect to the buried shield mask. In an implementation, the body contact mask 770 can be made from an oxide layer similar to the relatively thicker oxide layer 376 previously described, and thus, the relatively thinner oxide layer 372, the polysilicon layer 374, or both may or may not be present.

FIG. 8 includes a cross-sectional view along sectioning line 8-8 in FIG. 7 after forming body contact regions 852 and removing the body contact mask 770. The body contact regions 852 can be electrically coupled to the body region 232 and the buried shields 452, and in a particular implementation, can be electrically connected to a subsequently-formed source electrode. The body contact regions 852 are formed by doping the semiconductor layer 124 at locations below the body contact openings 772. The body contact regions 852 have the same conductivity type as the body region 232 and the buried shields 452. In an implementation, the body contact regions 852 are p-type doped.

The body contact regions 852 extend through the source regions 546 and the carrier accumulation regions 228 and to any depth within the buried shields 452. In an implementation, the body contact regions 852 extend from the major surface 126 to elevations within the buried shields 452 where the dopant concentration of the body contact regions 852 at such elevations is 1.1 times than the dopant concentration of the buried shields 452 at such elevations. In the same or a further different implementation, the body contact regions 852 extend from the major surface 126 to a depth in a range from 0.4 micron to 0.9 micron.

At elevations immediately adjacent to the source regions 546, the body contact regions 852 have a peak dopant concentration that is greater than the peak dopant concentration of the source regions 546. In the same or different implementation, the intermediate regions 552 have an average dopant concentration that is less than a peak dopant concentration of the body contact regions 852. In the same or different implementation, at elevations immediately adjacent to the source regions 546, the body contact regions 852 have a peak dopant concentration of at least 1×10¹⁹ atoms/cm³ and may have a peak dopant concentration that is at most 2×10²¹ atoms/cm³.

The body contact regions 852 may or may not have a dopant concentration that changes with elevation. For example, the body contact regions 852 can have a relatively higher dopant concentration at the same elevations as the source regions 546 and have a relatively lower dopant concentration at elevations below the source regions 546, where such relatively lower dopant concentration can be less than the peak dopant concentration of the source regions 546. The body contact regions 852 can extend through the deep portion 2282 and the shallow portion 2284 into the buried shields 452. Thus, the relatively lower dopant concentration of the body contact regions 852 can be greater than a peak dopant concentration of each of the shallow portion 2284 and the deep portion 2282. The body contact mask 770 can be removed at this point in the process.

An anneal can be performed to activate dopants with respect to the previously described doping operations. Before performing the anneal, a graphite capping layer can be formed over the workpiece to protect the SiC surface from sublimation, pitting, and other forms of surface roughening during the anneal. In an implementation, the graphite capping layer can have a thickness in a range from 1.5 microns to 5.0 microns. The capping layer can be deposited in the form of photoresist and reduced to a layer primarily composed of carbon during the subsequent anneal. The anneal can be performed for a soak time in a range from 10 minutes to 60 minutes at a temperature in a range from 1500° C. to 1800° C. The dopants within the workpiece may not significantly diffuse during the anneal, and thus, the doped layers and doped regions substantially may retain their shapes and locations are originally formed. In an implementation, the anneal can be performed in an inert ambient.

The anneal can be performed before or after forming gate trenches as described below. The anneal can be performed before forming a gate dielectric layer because a material within the gate dielectric layer may not be able to withstand the temperature used for the anneal. After reading this specification, skilled artisans will be able to determine where in the process flow the anneal is performed.

Many doping operations have been previously described. The order of performing the doping operations after forming the semiconductor layer 124 can be changed. For example, doping for the body contact regions 852 could be performed before any of the other doping operations previously described, such as doping for the carrier distribution layer 226, the carrier accumulation region 228, or the body region 232. Thus, before any anneal is performed, the doping operations can be performed in many different orders. In another implementation, another anneal may be performed after some but not all doping operations. Any doping operations performed before the other anneal is performed may not be performed after the other anneal, and any doping operations after the other anneal is performed may not be performed before the other anneal.

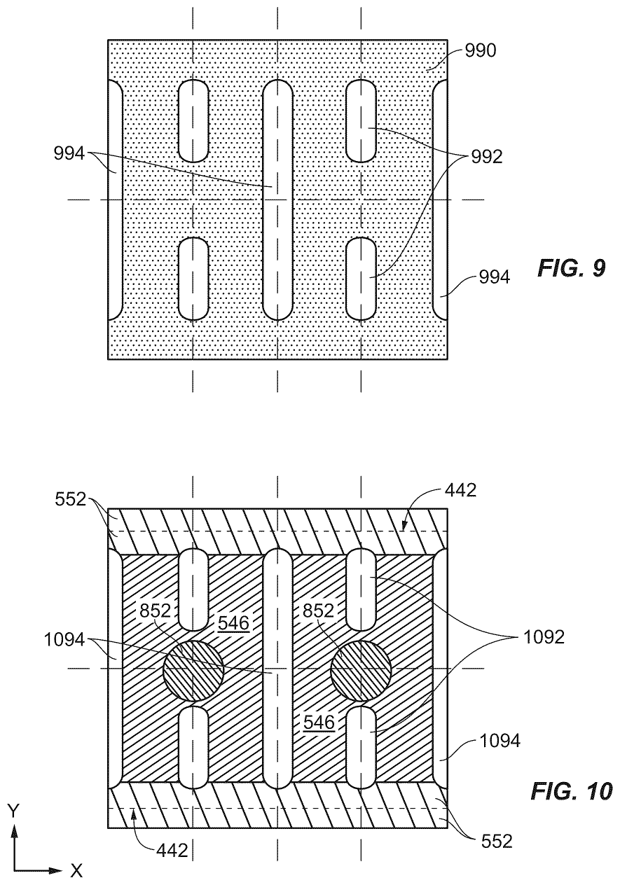

FIG. 9 includes a top view of a gate trench mask 990 over the major surface 126. The gate trench mask 990 defines openings 992 and 994 that are used to define gate trenches. The gate trench mask 990 can have the same or a different composition as previously described with respect to the prior hard masks.

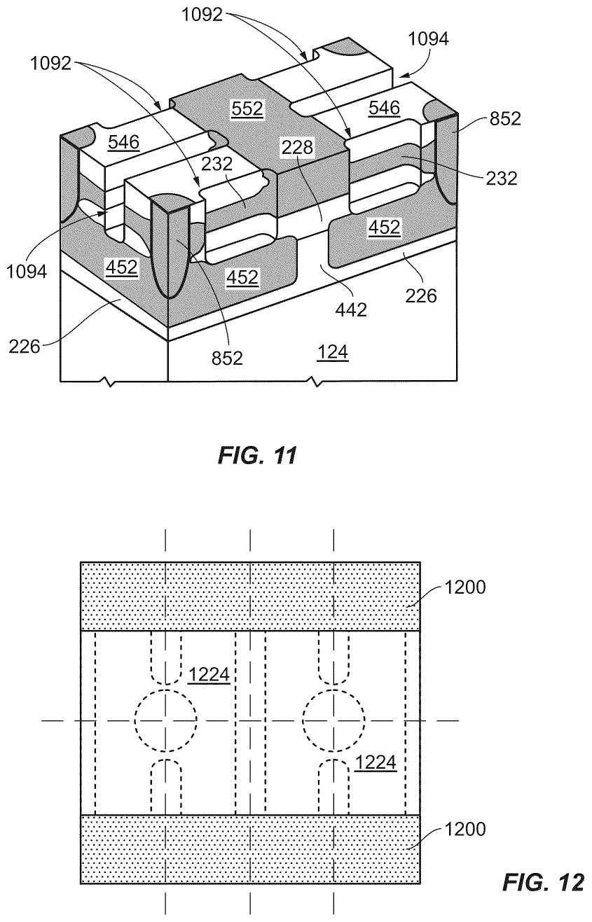

FIGS. 10 and 11 include a top view and a perspective view, respectively, of the workpiece after gate trenches 1092 and 1094 are defined and the gate trench mask 990 is removed. As illustrated, in FIG. 10, the gate trenches 1092 and 1094 can be in the form of segments. The gate trenches 1092 and 1094 are shared by at least two cells within an interior portion of the active cell array. As illustrated, the gate trenches 1092 are shared by two cells, and the gate trenches 1094 are shared by four cells.

The semiconductor material below the openings 992 and 994 of the gate trench hard mask 990 is etched to define the gate trenches 1092 and 1094. Referring to FIG. 11, the gate trenches 1092 and 1094 extend from the major surface 126 through the source regions 546 and the body region 232 and to at least the carrier accumulation regions 228. The gate trenches 1092 and 1094 contact the carrier accumulation regions 228. In an implementation, the bottoms of the gate trenches 1092 and 1094 may be at an elevation as deep as 0.05 micron from the top of the carrier distribution layer 226. In another implementation, the gate trenches 1092 and 1094 can extend through the carrier accumulation regions 228 and into the buried shields 452. In the same or different implementation, the gate trenches 1092 and 1094 do not extend completely through the buried shields 452. In the same or more particular implementation, the gate trenches 1092 and 1094 are spaced apart and do not contact the carrier distribution layer 226 or the underlying semiconductor layer 124. In any of the implementations described in this paragraph, the depths of the gate trenches 1092 and 1094 can be in a range from 0.3 micron to 1.1 microns.

In FIG. 10, the gap regions 442 are illustrated with dashed lines and are present below the intermediate regions 552 but not along the major surface 126. The gap region 442 near the top of FIG. 10 extends beyond the top of the illustration, and the gap region 442 near the bottom of FIG. 10 extends beyond the bottom of the illustration. In an implementation, the gate trenches 1092 and 1094 do not overlap the gap regions 442. Thus, a subsequently-formed gate dielectric layer will not be subjected to as high of an electrical field as compared to a gate dielectric layer that would contact the gap regions 442. In the same or different implementation, the gate trenches 1092 and 1094 may or may not extend into the intermediate regions 552.

Widths and lengths of the gate trenches 1092 and 1094 are measured along an X-Y plane corresponding to the major surface 126, and, for each gate trench, the length is greater than the width. The lengths of the gate trenches 1092 are less than the lengths of the gate trenches 1094. In an implementation, the lengths of the gate trenches 1092 can lie along lines that extend through the body contact regions 852. In the same or different implementation, the lengths of the gate trenches 1094 can lie along lines that do not extend through the body contact regions 852. The lengths of the gate trenches 1094 can be in a range from 1.1 to 5.0 times the lengths of the gate trenches 1092. The actual lengths of the gate trenches 1092 and 1094 may depend on the cell size and locations of the source regions 546, body contact regions 852, or gap regions 442, or a combination thereof. In the same or different implementation, the lengths of the gate trenches 1094 can be in a range from 0.7 micron to 5.0 microns. In the same or a further different implementation, the lengths of the gate trenches 1092 can be in a range from 0.2 micron to 3.0 micron to allow a reduced distance between gap regions 442.

In the implementation illustrated in FIG. 10, the widths of the gate trenches 1092 and 1094 can be selected to allow a cell to include portions of at least two gate trenches. As compared to a single gate trench, at least two gate trenches can help to increase the electrical channel width of the cell. In the X-direction in FIG. 10, widths of the gate trenches 1092 and 1094 can be the same or different from one another. In an implementation, the widths of the gate trenches 1094 can be in a range from 0.5 to 1.5 times the widths of the gate trenches 1092. The actual widths of the gate trenches 1092 and 1094 may depend on the cell size and locations of the body contact regions 852. In the same or different implementation, the widths of the gate trenches 1092 and 1094 can be in a range from 0.1 micron to 0.9 microns.

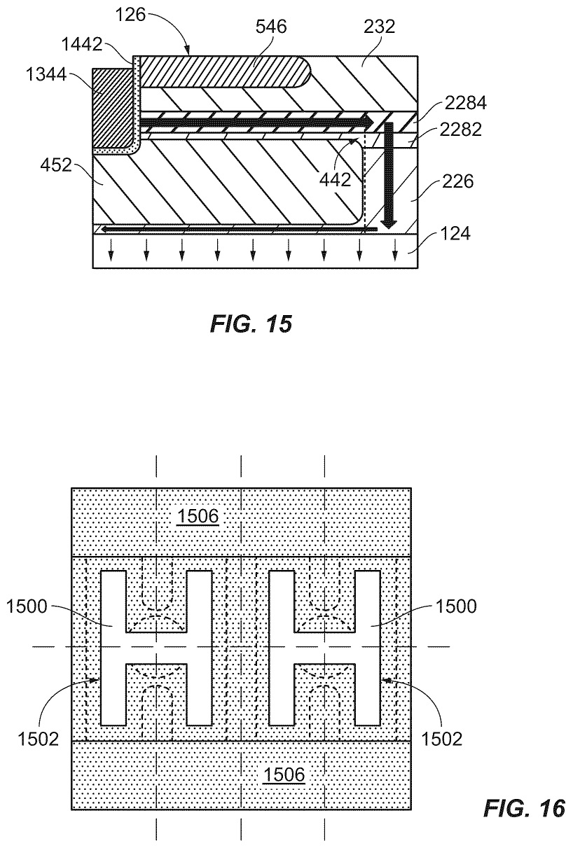

Referring to FIGS. 10 and 11 and illustrated in more detail in FIG. 15, in a finished device and when the power transistor is in an on-state, majority carriers flow along a path from the source regions 546, down (in the Z-direction, into the illustration of FIG. 10) through channel regions that are portions of the body region 232 that are adjacent to the sidewalls of the gate trenches 1092 and 1094, and into the carrier accumulation regions 228. The channel regions are located between their corresponding source regions 546 and carrier accumulation regions 228, and the channel regions are electrically coupled to their corresponding body contact regions 852. The majority carriers can flow along a path to the semiconductor layer 124 via the gap regions 442. In an implementation, the majority carriers can flow through portions of the carrier accumulation region 228 and the carrier distribution layer 226 that are outside the gap regions 442.

Referring to FIG. 10, the majority carriers flow within the carrier accumulation regions 228 along a path toward the gap regions 442 near the top and bottom of FIG. 10. Thus, majority carriers principally flow along a path in the Y-direction in FIG. 10. The lengths of the gate trenches 1092 and 1094 are in the Y-direction. Thus, the lengths of the gate trenches 1092 and 1094 are parallel to the principal flow of majority carriers within the shallow portion 2284. If the lengths of the gate trenches 1092 and 1094 were perpendicular to the principal flow of majority carriers within the shallow portion 2284, the current flowing through the power transistor would be substantially less. Depending on the physical layout and depth of the gate trenches 1092 and 1094, some of the carrier accumulation regions 228 may be electrically isolated from the gap regions 442, or majority carriers may flow a relatively long distance before reaching any of the gap regions 442, or part of the body region 232 may be isolated from the body contact regions 852. One exception is the case of a single continuous trench over the buried shields 452 that is perpendicular to the principal flow of majority carriers within the shallow portion 2284. In this case, no isolation of carrier accumulation regions 228 or body region 232 occurs.

If the previously described anneal was not performed before defining the gate trenches 1092 and 1094, the anneal can be performed after defining the gate trenches 1092 and 1094. The anneal can be performed before forming a gate dielectric layer. When the anneal is performed after defining the gate trenches 1092 and 1094, the graphite capping layer may fill or at least partially fill the gate trenches 1092 and 1094.

A gate dielectric layer (labelled as layer 1442 in FIG. 14) can be formed along exposed surfaces of the workpiece, including sidewalls and bottoms of the gate trenches 1092 and 1094 and over portions of the source regions 546 and the intermediate regions 552 lying along the major surface 126. In an implementation, the gate dielectric layer is spaced apart from and does not contact the gap regions 442. The electrical field across the gate dielectric layer is substantially lower than it would be if any of the gate trenches 1092 and 1094 exposed a portion of the gap regions 442. Thus, the gate dielectric layer may be less susceptible to long term reliability issues. The gate dielectric layer can include an oxide or an oxynitride. In an implementation, the gate dielectric layer can have a thickness in a range from 20 nm to 150 nm.

Referring to FIG. 12, a gate conductive layer 1224 can be deposited over the gate dielectric layer. The gate conductive layer 1224 can include a single film or a plurality of films, where the single film or any of the films within the plurality of films can include a doped semiconductor layer, an elemental metal (a metal that is not part of an alloy and not part of a compound, such as W, Cu, Al, etc.), a metal alloy (for example, TiW, Al-1wt % Cu, or the like), or a conductive metal compound (for example, a conductive metal silicide or a conductive metal nitride). The gate conductive layer 1224 can have a thickness sufficient to fill the gate trenches 1092 and 1094. In a particular implementation, the gate conductive layer 1224 can be n-type doped polysilicon.

A gate photoresist mask 1200 is formed over portions of the gate conductive layer 1224. Referring to FIGS. 10 and 12, the photoresist mask 1200 overlaps the intermediate regions 552 and portions of the source regions 546 and gate trenches 1092 and 1094 adjacent to the intermediate regions 552.

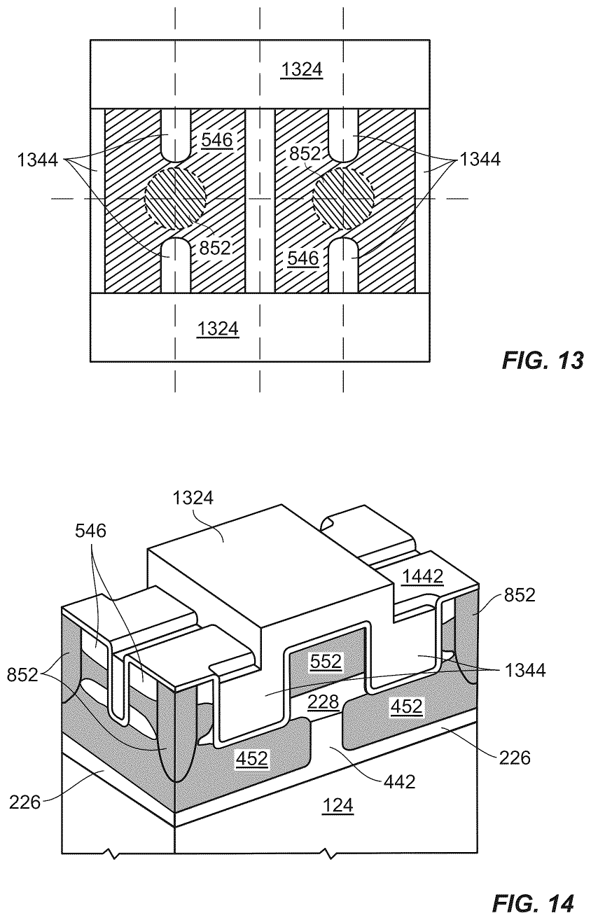

Referring to FIGS. 12 to 14, exposed portions of the gate conductive layer 1224 are etched to form gate members 1324, and the gate photoresist mask 1200 is removed. Although the gate dielectric layer 1442 is exposed in FIG. 13, the gate dielectric layer 1442 is not labelled in FIG. 13 to allow other features to be identified. Portions of the gate members 1324 overlap the intermediate regions 552 and the gap regions 442. The intermediate regions 552 are located between the portions of the gate members 1324 and the gap regions 442. The gate members 1324 include (1) gate electrodes 1344 that extend into the gate trenches 1092 and 1094 and (2) intermediate portions between the gate electrodes 1344 and overlapping the intermediate regions 552 and the gap regions 442.

The etch can be performed to remove portions of the gate conductive layer 1224 that are not covered by the gate photoresist mask 1200. The etch can be performed as a timed etch or with endpoint detection and an overetch. Endpoint detection can occur when the gate dielectric layer 1442 is exposed. The overetch can be performed to recess portions of the gate members 1324 within the gate trenches 1092 and 1094 to reduce gate-to-source capacitance, Cos. The elevation along the recessed portions of the gate member are no lower than the lowermost points of the source regions 546. In another implementation, relatively higher Cos may be acceptable, and the gate members 1324 may not be recessed within the gate trenches 1092 and 1094. The gate photoresist mask 1200 can be removed after the gate members 1324 are formed.

As illustrated in FIG. 14, the gate dielectric layer 1442 is located between the gate electrodes 1344 and sidewalls of the gate trenches 1092 and 1094. If needed or desired, a silicide process can be performed to silicide exposed surfaces of the gate members 1324 when the gate members 1324 include doped polysilicon. FIG. 14 and perspective views of other figures provide a better understanding of how the transistor structures appear from a three-dimensional view. The shapes of some features in the perspective views may slightly differ from the two-dimensional drawings; however, the differences are insignificant and do not significantly deviate from the concepts described herein.

FIG. 15 includes a cross-sectional view of a portion of a transistor structure to illustrate majority carrier flow from the carrier accumulation region 228, which includes the shallow portion 2284 and the deep portion 2282, to the semiconductor layer 124 when the transistor is in an on-state. The majority carrier flow is illustrated with the arrows. Majority carriers are electrons for an n-channel transistor and holes for a p-channel transistor. The majority carriers from the source region flow from the source region 546 through the channel region, which is the portion of the body region 232 along the gate trench, to the carrier accumulation region 228. As illustrated with solid arrows, majority carriers flow laterally within the shallow portion 2284 and the deep portion 2282, vertically through the gap region 442, and laterally within the portion of the carrier distribution layer 226 that underlaps most of the buried shield 452. The majority carriers can then flow into the semiconductor layer 124. Thus, the carrier distribution layer 226 helps to distribute more uniformly the majority carriers into semiconductor layer 124 as compared to transistor structure where the carrier distribution layer 226 would have been restricted only to the gap region 442 or where the carrier distribution layer 226 is replaced by the semiconductor layer 124 (the semiconductor layer 124 would have extended into the gap region 442 and contact the carrier accumulation region 228).

An interlevel dielectric (ILD) layer 1500 and a contact photoresist mask 1506 can be formed over the workpiece as illustrated in FIG. 16. The ILD layer 1500 can include a single film or a plurality of films. The single film or any one or more of the films of the within the plurality of films can include an oxide, a nitride, or an oxynitride. The single film or any one or more of the films of the within the plurality of films may or may not be doped with boron, phosphorus, or the like. The ILD layer 1500 can be deposited to a thickness in a range from 0.5 micron to 3.0 microns. A planarization process can be performed so that the uppermost surface of the ILD layer 1500 lies along a plane. The planarization process can be performed using chemical mechanical polishing or a resist etch-back process.

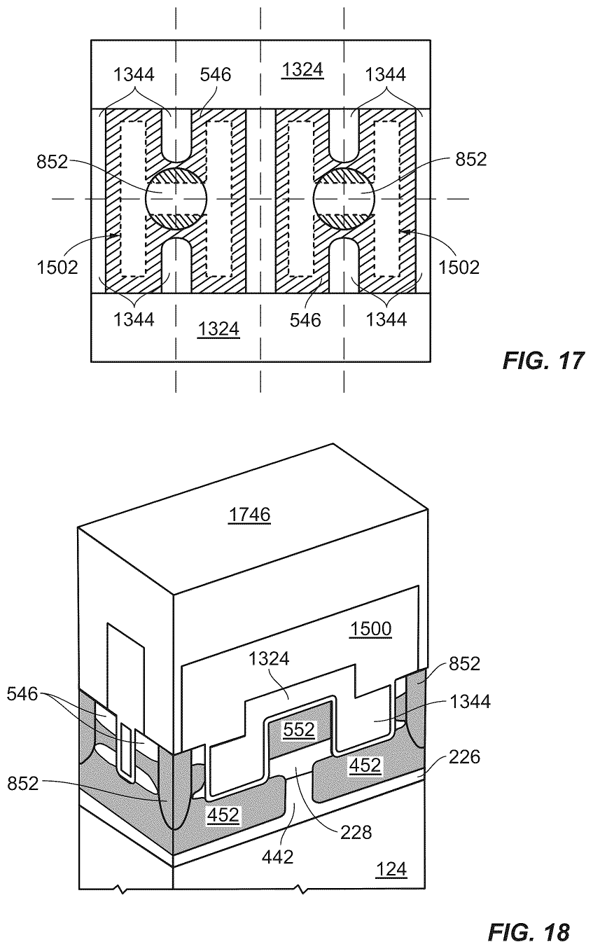

The contact photoresist mask 1506 defines openings 1502 that expose portions of the ILD layer 1500. Referring to FIGS. 13 and 16, the openings 1502 are H-shaped and allow a subsequently-formed source electrode to contact the source regions 546 and the body contact regions 852. In an implementation, the openings 1502 are spaced apart from the gate members 1324 including the gate electrodes 1344. FIG. 17 includes an illustration of the workpiece in FIG. 13 with the H-shaped openings superimposed as dashed lines to provide a better understanding of the positional relationships between the openings 1502 and other features within the power transistor. After the ILD layer 1500 is etched to expose portions of the source regions 546 and the body contact regions 852, the contact photoresist mask is removed. Although not illustrated, openings to the gate members 1324 are at locations outside the portions of the workpiece as illustrated in the figures.

A conductive layer is deposited over the ILD layer 1500 and within contact openings extending through the ILD layer to contact the source regions 546, the body contact regions 852, and the gate members 1324. The conductive layer can include one or more films, wherein each film includes a conductive material. In an implementation, the conductive material can include a doped semiconductor material, an elemental metal (a metal that is not part of a compound or an alloy), a metal alloy, or a conductive metallic compound. A non-limiting example of a conductive material can be doped polysilicon (n-type or p-type), W, WN, Ti, Ta, TiW, Al-1 wt % Cu, Ni, Cu, Au, Pt, a conductive metal nitride (e.g., WN, ToN, TaN, etc.), a conductive metal silicide (TiSi₂, CoSi₂, PtSi, etc.), or the like. In an implementation, the conductive layer can be deposited to a thickness in a range from 0.7 micron to 5.0 microns.

A photoresist mask is formed over the conductive layer and patterned to form a source electrode 1746 in FIG. 18 and a gate terminal (not illustrated). The source terminal 1746 contacts the source regions 546 and body contact regions 852. In an implementation, ohmic contacts are formed between the source terminal 1746 and the source regions 546 and the body contact regions 852. The gate terminal contacts the gate members 1324.

If needed or desired, a passivation layer (not illustrated) can be formed over the ILD layer 1500, the source electrode 1746, and the gate terminal. The passivation can include one or more films of a insulating material. In a particular implementation, the passivation layer includes polyimide that is coated and patterned to expose portions of the source electrode 1746 and the gate terminal. The reverse side of the workpiece may be provided with a metal layer that is a drain terminal and contacts the substrate 122.

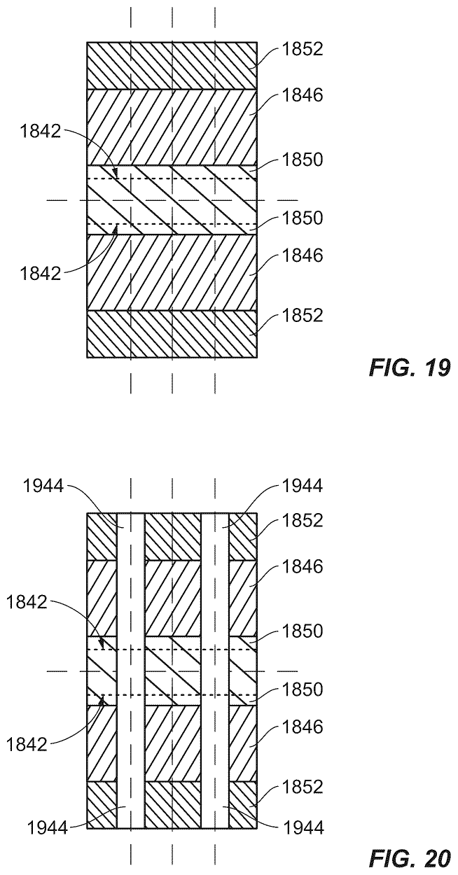

In another implementation illustrated in FIGS. 19 to 23, continuous gate trenches, rather than segmented gate trenches may be used. FIG. 19 includes a top view of a portion of the power transistor and is at a point in processing as illustrated in FIG. 8 and before the gate trenches are defined. As compared to the doped regions in FIG. 8, the doped regions in FIGS. 19 to 23 are at different locations.

The semiconductor layer 124, the carrier distribution layer 226, the deep portion 2282, the shallow portion 2284, and the body region 232 are formed as previously described. The workpiece in FIG. 19 includes a different set of masks used to form the electronic device. In FIGS. 19, 20, and 22, the longer dashed lines correspond to borders of cells within a power transistor. The design as illustrated in FIG. 19 includes two rows and four columns of cells in a 2×4 configuration. Many other cells are present within the power transistor but are not illustrated in FIG. 19.

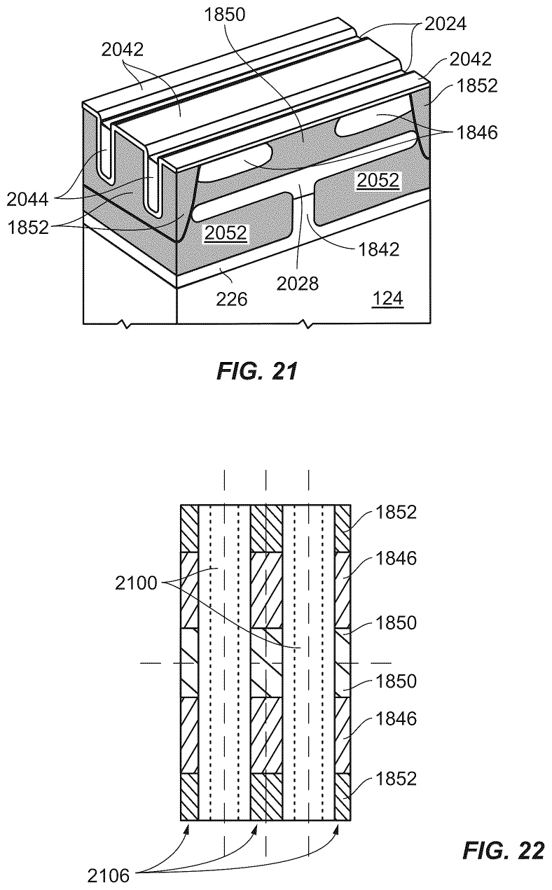

Referring to FIG. 2, the semiconductor layer 124, the carrier distribution layer 226, the deep portion 2282, the shallow portion 2284, and the body region 232 are formed as previously described. In FIG. 19, source regions 1846 are formed over all of the workpiece as illustrated with the exception of the intermediate region 1850 that is the portion of the body region 232 between the source regions 1846. Gap region 1842 underlies the intermediate region 1850 and has borders illustrated with dashed lines. Referring briefly to FIG. 21, the buried shields 2052 and the carrier accumulation regions 2028 have substantially the same positional relationships to the source regions 1846 as the buried shields 452 and the carrier accumulation regions 228 to the source regions 546. A buried shield hard mask can be used to form the source regions 1846, the carrier accumulation regions 2028, and the buried shields 2052. A body contact mask can be used to form the body contact regions 1852. The buried shields 2052, the carrier accumulation regions 2028, the source regions 1846, and the body contact regions 1852 can have the same conductivity type, any of the dopant concentrations, dopant concentration profiles, and depths as previously described with respect to the buried shields 452, the carrier accumulation regions 228, the source regions 546, and the body contact regions 852, respectively.

An anneal can be performed to activate dopants within the doped regions. The anneal can be performed at any of the temperatures and soak times as previously described with respect to the anneal of workpiece as illustrated in FIGS. 1 to 18. The anneal can be performed at any of the times in the process flow as previously described.

A gate trench mask can be formed, exposed semiconductor material can be etched to define gate trenches, and the gate trench mask can be removed after defining the gate trenches. FIG. 20 includes the workpiece after the gate trenches 1944 are defined. The trenches 1944 are continuous through the cells. Near the center of FIG. 20, the gap regions 1842 can be exposed within the gate trenches 1944.

Referring to FIG. 21, a gate dielectric layer 2042 and a gate conductive layer are formed over the major surface and within the gate trenches 1944. The gate dielectric layer 2042 and the gate conductive layer can have any of the compositions and thicknesses as previously described with respect to the gate dielectric layer 1442 and the gate conductive layer 1224, respectively, used in forming the gate members 1324. A gate photoresist mask can be formed over a portion of the gate conductive layer at a location where a subsequently-formed gate terminal will contact the gate conductive members. The gate conductive layer is etched and partly recessed within the gate trenches to form the gate members 2024. The portions of the gate members 2024 in FIG. 21 are gate electrodes 2044 for transistor structures of the power transistor. The etch for the gate members 2024 can be performed using any of the techniques previously described with respect to etching to form the gate members 1324.

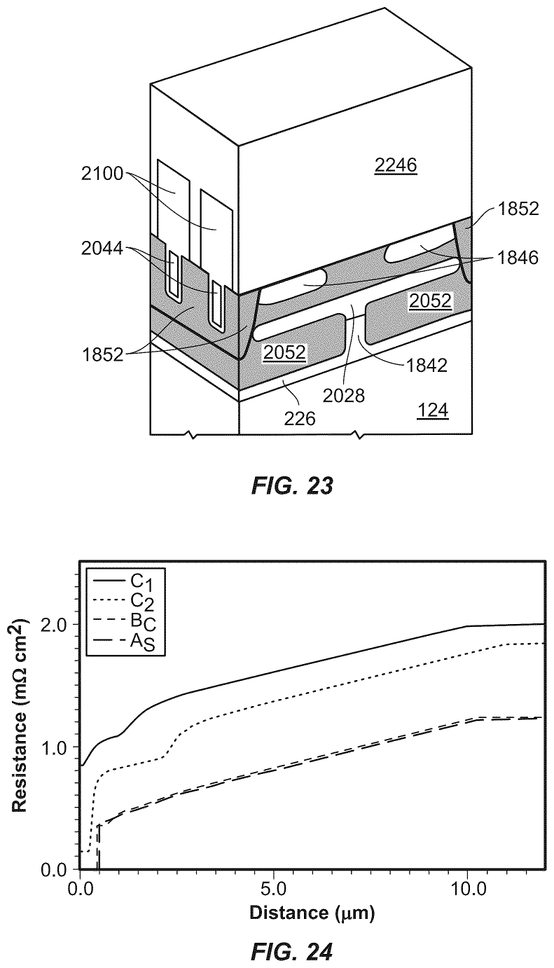

FIG. 22 includes the workpiece after an ILD layer 2100 is formed over the workpiece and patterned to define contact openings 2106. The location of the gate trenches are illustrated with the dashed lines within the ILD layer 2100. FIG. 23 includes the workpiece after forming a source terminal 2246 and a gate terminal (not illustrated in FIG. 23). The source terminal 2246 and the gate terminal can have any of the materials and design considerations as previously described with respect to the source terminal 1746 and gate terminal regarding FIG. 18.

The continuous gate trench design of the power transistor in FIGS. 19 to 23 is a simpler design compared to the segmented gate trench design in FIGS. 10 to 18. The continuous gate trench design may allow the gate dielectric layer 2042 to contact the gap regions 1842. The electrical field across the gate dielectric layer 2042 may make it more susceptible to a long-term reliability issue as compared to the segmented gate trench design. In addition, Al may migrate more readily into the gate dielectric layer 2042 from the heavily-doped body contact regions 1852, which again may make the gate dielectric layer 2042 more susceptible to a long-term reliability issue. This issue is avoided in the segmented gate trench design because the gaps between the ends of trench segments 1092 allow for a greater spacing from the heavily-doped body contact regions 852. Further, gate-to-drain capacitance, CGD, is greater for the continuous gate trench design as compared to the segmented gate trench design.

Many different aspects and implementations are possible. Some of those aspects and implementations are described below. After reading this specification, skilled artisans will appreciate that those aspects and implementations are only illustrative and do not limit the scope of the inventive concepts. Implementations may be in accordance with any one or more of the implementations as listed below.

Implementation 1. An electronic device can include a transistor, wherein the transistor includes a substrate having a first conductivity type; a carrier accumulation region having the first conductivity type; a buried shield having a second conductivity type opposite the first conductivity type, and a gap region having the first conductivity type. The buried shield can be between the carrier accumulation region and the substrate. A mid-elevation line can be where half of a thickness of the buried shield is above the mid-elevation line, and another half of the thickness of buried shield is below the mid-elevation line. The gap region can be defined at least in part by the buried shield. The gap region can be along a majority carrier flow path between substrate and a portion of the carrier accumulation region overlapping the buried shield. The carrier accumulation region can have a peak dopant concentration that is greater than a dopant concentration of the gap region along a mid-elevation line.

Implementation 2. The electronic device of Implementation 1 further includes a body region having the second conductivity type, wherein the carrier accumulation region is between the body region and the buried shield.

Implementation 3. The electronic device of Implementation 2 further includes a body contact region having the second conductivity type and electrically coupled to the buried shield and the body region, wherein the body contact region extends to an elevation below the carrier accumulation region.

Implementation 4. The electronic device of Implementation 3, wherein an elevational difference between a lowermost point of the buried shield and an uppermost surface of the body contact region is at most 2 microns.

Implementation 5. The electronic device of Implementation 4, wherein the transistor includes the substrate, the gap region, the carrier accumulation region, the buried shield, the body region, and the body contact region, and the transistor has BVDs of at least 600 V.

Implementation 6. The electronic device of Implementation 3 further includes a first source region spaced apart from the carrier accumulation region by at least a portion of the body region.

Implementation 7. The electronic device of Implementation 6 further includes a second source region, wherein the first source region is a part of a first cell, the second source region is a part of a second cell that is different from the first cell.

Implementation 8. The electronic device of Implementation 7 further includes an intermediate region having the second conductivity type and having a dopant concentration less than the body contact region, wherein the intermediate region is between the first source region and the second source region and over the gap region.

Implementation 9. The electronic device of Implementation 8 further includes a gate member, wherein an intermediate portion of the gate member overlaps the intermediate region and the gap region.

Implementation 10. The electronic device of Implementation 2 further includes a gate trench that extends through the body region and contacts the carrier accumulation region.

Implementation 11. The electronic device of Implementation 10 further includes a gate member including a gate electrode within the gate trench; and a gate dielectric layer is between the gate electrode and a sidewall of the gate trench.

Implementation 12. The electronic device of Implementation 1, wherein, from a cross-sectional view, a width of the buried shield is greater than a width of the gap region.

Implementation 13. The electronic device of Implementation 1 further includes a carrier distribution layer, wherein a portion of the carrier distribution layer is within the gap region.

Implementation 14. An electronic device can include a substrate having a first conductivity type; a carrier distribution layer having the first conductivity type; a gap region having the first conductivity type; a carrier accumulation region having the first conductivity type; and a body region having a second conductivity type and including a channel region of a vertical transistor above the carrier accumulation region. A portion of the carrier distribution layer can be within the gap region, the gap region can be along a majority carrier flow path between the carrier accumulation region and the carrier distribution layer, and a peak dopant concentration of the carrier distribution layer can be greater than a background dopant concentration.

Implementation 15. The electronic device of Implementation 14 further includes a buried shield between the carrier accumulation region and the substrate and having the second conductivity type.

Implementation 16. The electronic device of Implementation 15 further includes a body contact region electrically coupled to the buried shield and extending to an elevation below a lowermost point of the carrier accumulation region.

Implementation 17. An electronic device can include a substrate having a first conductivity type; a carrier accumulation region having the first conductivity type and electrically coupled to the substrate; a first source region having the first conductivity type, wherein the first source region is a part of a first vertical transistor structure; a second source region having the first conductivity type, wherein the second source region is a part of a second vertical transistor structure; and an intermediate region having a second conductivity type opposite the first conductivity type, wherein the intermediate region is laterally between the first source region and the second source region and at an elevation higher than the carrier accumulation region The electronic device can further include a first gate trench extending through the first source region; a second gate trench extending through the second source region; and a gate member having a portion lying within the first gate trench, another portion lying within the second gate trench, and an intermediate portion overlapping the intermediate region, wherein the gate member includes a first gate electrode for the first vertical transistor structure and a second gate electrode for the second vertical transistor structure.

Implementation 18. The electronic device of Implementation 17, wherein upper surfaces of the intermediate region, the first source region, and the second source region lie along a major surface.

Implementation 19. The electronic device of Implementation 17 further includes a first channel region between the first source region and the carrier accumulation region; and a second channel region between the second source region and the carrier accumulation region.

Implementation 20. The electronic device of Implementation 19 further includes a body contact region having the second conductivity type and electrically coupled to the first channel region and the second channel region.

Implementation 21. The electronic device of Implementation 17 further includes a gate dielectric layer between the first gate electrode and a sidewall of the first gate trench.

### EXAMPLES

The segmented gate trench and continuous gate trench designs as described herein can provide better electrical characteristics compared to conventional designs. The examples are meant to improve understanding of the concepts described herein and not to limit the present inventive concepts.

Four simulations were performed on four different designs for power transistors:
A_{S}—the segmented gate trench design described above;
B_{C}—the continuous gate trench design described above;
C₁—A first control design with a planar gate structure;
C₂—A second control design with a trench gate structure without any of a carrier distribution layer, a carrier accumulation region, and a buried shield.

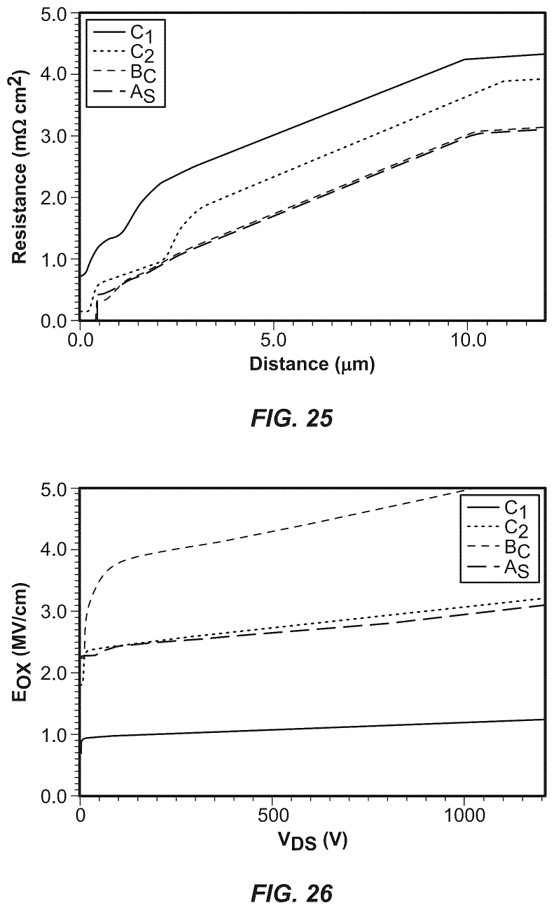

FIGS. 24 and 25 include R_{SP} profiles as a function of vertical distance. FIG. 24 corresponds to data for 25° C., and FIG. 25 corresponds to data for 175° C. Referring to FIG. 24, at depths in a range from 3.5 microns to 10.0 microns, C₁ has an R_{SP} that is approximately 0.8 mΩ-cm² higher than R_{SP} for A_{S} and B_{C}, and C₂ has an R_{SP} that is approximately 0.5 mΩ-cm²higher than R_{SP} for A_{S} and B_{C}. Referring to FIG. 25, at depths in a range from 3.5 microns to 10.0 microns, C₁ has an R_{SP} that is approximately 1.3 m2-cm² higher than R_{SP} for A_{S} and B_{C}, and C₂ has an R_{SP} that is approximately 0.6 Ω-cm² higher than R_{SP} for A_{S} and B_{C}. The A_{S} and B_{C}designs have significantly better R_{SP} at 25° C. and 175° C. as compared to the C₁ and C₂ designs.

FIG. 26 include plots of maximum electrical field across a gate dielectric layer, E_{OX}, as a function of V_{DS} for the four designs. As previously described, the gate electrodes 2044 for the B_{C} design overlap the gap regions 1842, and the gate dielectric layer 2042 can contact the gap regions 1842. Referring to FIG. 26, for the designs when V_{DS} is in a range from 150 V to 1000 V, E_{OX} increases linearly with voltage. For any V_{DS} within the linear portions of the plots, the B_{C} design has the highest E_{OX}. When V_{DS} is 800 V, the B_{C} design has an E_{OX} that is approximately 70% higher than E_{OX} for the A_{S} and C₂ designs and approximately 320% higher than E_{OX} for the C₁ design. When V_{DS} is 800 V, the As design has a E_{OX} that is approximately 4% lower than E_{OX} for the C₂ design and approximately 250% higher than E_{OX} for the C₁ design. Thus, the As design has approximately the same E_{OX} as the C₂ design. The Be design has a substantially higher E_{OX} as compared to the other designs. Devices with a higher E_{OX} may have a higher susceptibility to long-term gate dielectric layer reliability issues.

The As design as illustrated in FIGS. 1 to 18 and described in the corresponding text can provide a design that has very good electrical performance without the higher E_{OX} and the higher C_{GD}, and potential long-term reliability issue for the B_{C} design that has a gate dielectric layer 2042 that contacts the gap regions 1842.

Both the A_{S} and the B_{C} designs can allow for smaller vertical (Z-direction) dimensions for transistor structures. The lowermost points of the buried shields can be at an elevation less than 2.0 microns from the uppermost points of the corresponding body contact regions. In an implementation, the elevational difference is no more than 1.2 microns, and an elevational difference of 0.9 micron and lower may be achieved with the designs described herein.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that may cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations may also be provided in combination in a single implementation, and conversely, various features that are, for brevity, described in the context of a single implementation, may also be provided separately or in any subcombination. Further, reference to values stated in ranges includes each and every value within that range. Many other implementations may be apparent to skilled artisans only after reading this specification. Other implementations may be used and derived from the disclosure, such that a structural substitution, logical substitution, or another change may be made without departing from the scope of the disclosure. Accordingly, the disclosure is to be regarded as illustrative rather than restrictive.

1. An electronic device, comprising a transistor, wherein the transistor comprises:
a substrate having a first conductivity type;
a carrier accumulation region having the first conductivity type;
a buried shield having a second conductivity type opposite the first conductivity type and being between the carrier accumulation region and the substrate, wherein a mid-elevation line is where half of a thickness of the buried shield is above the mid-elevation line, and another half of the thickness of buried shield is below the mid-elevation line;
a gap region having the first conductivity type, wherein the gap region is defined at least in part by the buried shield; and
a carrier distribution layer, wherein the buried shield overlaps a portion of the carrier distribution layer,
wherein:
the gap region is along a majority carrier flow path between substrate and a portion of the carrier accumulation region overlapping the buried shield, and
the carrier accumulation region has a peak dopant concentration that is greater than a dopant concentration of the gap region along the mid-elevation line.

2. The electronic device of claim 1, further comprising:
a body region having the second conductivity type, wherein the carrier accumulation region is between the body region and the buried shield.

3. The electronic device of claim 2, further comprising:
a body contact region having the second conductivity type and electrically coupled to the buried shield and the body region, wherein the body contact region extends to an elevation below the carrier accumulation region.

4. The electronic device of claim 3, wherein an elevational difference between a lowermost point of the buried shield and an uppermost surface of the body contact region is at most 2 microns.

5. The electronic device of claim 4, wherein the transistor includes the substrate, the gap region, the carrier accumulation region, the buried shield, the body region, and the body contact region, and the transistor has BVDs of at least 600 V.

6. The electronic device of claim 3, further comprising:
a first source region spaced apart from the carrier accumulation region by at least a portion of the body region.

7. The electronic device of claim 6, further comprising:
a second source region, wherein the first source region is a part of a first cell, the second source region is a part of a second cell that is different from the first cell.

8. The electronic device of claim 7, further comprising:
an intermediate region having the second conductivity type and having a dopant concentration less than the body contact region, wherein the intermediate region is between the first source region and the second source region and over the gap region.

9. The electronic device of claim 8, further comprising:
a gate member, wherein an intermediate portion of the gate member overlaps the intermediate region and the gap region.

10. The electronic device of claim 2, further comprising:
a gate trench that extends through the body region and contacts the carrier accumulation region.

11. The electronic device of claim 10, further comprising:
a gate member including a gate electrode within the gate trench; and
a gate dielectric layer is between the gate electrode and a sidewall of the gate trench.

12. The electronic device of claim 1, wherein, from a cross-sectional view, a width of the buried shield is greater than a width of the gap region.

13. The electronic device of claim 1, the carrier accumulation region extends across all of a width of the gap region.

14. An electronic device, comprising:
a substrate having a first conductivity type;
a buried shield having a second conductivity type opposite the first conductivity type;
a gap region having the first conductivity type, wherein the gap region is defined at least in part by the buried shield;
a first gate trench extending to the buried shield and spaced apart from the gap region;
a second gate trench extending to the buried shield and spaced apart from the gap region and the first gate trench; and
a gate member having a portion lying within the first gate trench, another portion lying within the second gate trench, and an intermediate portion overlapping the gap region, wherein the gate member includes a first gate electrode for a first vertical transistor structure and a second gate electrode for a second vertical transistor structure.

15. The electronic device of claim 14, further comprising:
a source region having the first conductivity type;
a carrier accumulation region having the first conductivity type, wherein the carrier accumulation region underlaps and is spaced from the source region, and a portion of the carrier accumulation region overlaps the buried shield; and
a carrier distribution layer having the first conductivity type, wherein a portion of the carrier distribution layer underlaps the buried shield.

16. The electronic device of claim 15, further comprising a body contact region electrically coupled to the buried shield and extending to an elevation below a lowermost point of the carrier accumulation region.

17. An electronic device, comprising:
a substrate having a first conductivity type;
a carrier accumulation region having the first conductivity type and electrically coupled to the substrate;
a first source region having the first conductivity type, wherein the first source region is a part of a first vertical transistor structure;
a second source region having the first conductivity type, wherein the second source region is a part of a second vertical transistor structure;
an intermediate region having a second conductivity type opposite the first conductivity type, wherein the intermediate region is laterally between the first source region and the second source region and at an elevation higher than the carrier accumulation region;
a first gate trench extending through the first source region;
a second gate trench extending through the second source region; and
a gate member having a portion lying within the first gate trench, another portion lying within the second gate trench, and an intermediate portion overlapping the intermediate region, wherein the gate member includes a first gate electrode for the first vertical transistor structure and a second gate electrode for the second vertical transistor structure.

18. The electronic device of claim 17, wherein upper surfaces of the intermediate region, the first source region, and the second source region lie along a major surface.

19. The electronic device of claim 17, further comprising:
a first channel region between the first source region and the carrier accumulation region; and
a second channel region between the second source region and the carrier accumulation region.

20. The electronic device of claim 19, further comprising:
a body contact region having the second conductivity type and electrically coupled to the first channel region and the second channel region.

21. The electronic device of claim 17, further comprising:
a gate dielectric layer between the first gate electrode and a sidewall of the first gate trench.
